(19) United States
(12) Patent Application Publication
(10) Pub. No.: US 2025/0076412 A1
(43) Pub. Date: Mar. 6, 2025

(54) DETECTION OF DEFECTIVE AND UNDERPERFORMING CURRENT TRANSFORMERS

(71) Applicant: FLORIDA POWER & LIGHT COMPANY, Juno Beach, FL (US)

(72) Inventors: JORGE L. CARBONELL, MIAMI, FL (US); EDWARD SANCHEZ, HIALEAH, FL (US); JOSE L. BRITO, MIAMI, FL (US); EDUARDO SOTOLONGO, DORAL, FL (US)

(21) Appl. No.: 18/458,766

(22) Filed: Aug. 30, 2023

(51) Int. Cl. G01R 31/62

(52) U.S. Cl. CPC G01R 31/62

(57) ABSTRACT

A current transformer (CT) monitor receives power data from a metering device operating on a customer premises, the power data characterizing features of electrical power provided to the customer premises. The CT monitor also determines, from the power data, an operational condition of a set of CTs of the metering device installed at the customer premises based on the power data, wherein the operational condition of the set of CTs impacts an ability to accurately calculate a demand of power consumed by the customer premises.

### TECHNICAL FIELD

The present disclosure relates to detection of defective and underperforming current detectors installed at customer premises.

### BACKGROUND

A current transformer (CT) is a type of transformer that is used to reduce or multiply an alternating current (AC). CTs have a primary winding and a secondary winding. A CT produces a current in a secondary winding which is proportional to the current in a primary winding. Current transformers, along with voltage or potential transformers, are instrument transformers. Instrument transformers scale the large values of voltage or current into small, standardized values that are easy to handle for measuring instruments and protective relays. The instrument transformers isolate measurement or protection circuits from the high voltage of the primary system. A current transformer provides a secondary current on the secondary winding that is accurately proportional to the current flowing in the primary winding. The current transformer presents a negligible load to a circuit coupled to the primary winding.

### SUMMARY

One example relates to a non-transitory machine-readable medium having machine-readable instructions for a current transformer (CT) monitor, the machine-readable instructions for the CT monitor being executable by a processor core to perform operations. The operations include receiving power data from a metering device operating on a customer premises, the power data characterizing features of electrical power provided to the customer premises. The operations of the CT monitor also include determining, from the power data, an operational condition of a set of CTs of the metering device installed at the customer premises based on the power data, wherein the operational condition of the set of CTs impacts an ability to accurately calculate a demand of power consumed by the customer premises. The inability to accurately calculate the power consumed by the customer premises, inhibits the ability of a power provider to accurately invoice customer consumption.

Another example relates to a system for monitoring current transformers (CTs). The system includes a non-transitory memory having machine-readable instructions and a processor core that accesses the memory and executes the machine-readable instructions. The machine-readable instructions include a CT monitor that receives power data from a metering device operating on a customer premises, the power data characterizing a single or polyphase power provided to the customer premises, the power data characterizing a voltage magnitude, a voltage angle, a voltage phase, a current magnitude, a current angle and a current phase for phases of a single or polyphase power provided to the customer premises. The CT monitor also determines, based on the power data, an operational condition of a set of CTs of the metering device installed at the customer premises based on the power data, and each CT in the set of CTs is coupled to a corresponding power line of the single or polyphase power.

Yet another example relates to a method for monitoring current CTs. The method includes receiving, at a CT monitor executing on a server, power data from a metering device operating on a customer premises for power data for single or polyphase power provided to the customer premises, the power data characterizing a voltage magnitude, a voltage angle, a voltage phase, a current magnitude, a current angle and a current phase for phases of the single or polyphase power provided to the customer premises. The method also includes determining, based on the power data, an operational condition of a set of CTs of the metering device installed at the customer premises based on the power data, and each CT in the set of CTs is coupled to a corresponding power line of the single or polyphase power.

### BRIEF DESCRIPTION OF THE DRAWINGS

FIG. 1 illustrates an example of a system for monitoring operational conditions of current transformers (CTs).

FIG. 2 illustrates pseudocode for detecting if a CT installed in a metering device at a customer premises is connected backwards.

FIG. 3 illustrates pseudocode for detecting if a CT installed in a metering device at a customer premises is defective.

FIG. 4 illustrates pseudocode for detecting if a CTs installed in a metering device at a customer premises is defective are oversized.

FIG. 5 illustrates pseudocode for detecting if a CTs installed in a metering device at a customer premises are cross-phased.

FIG. 6 illustrates an example of a dashboard provided by a UI generator for viewing a status of customer premises.

FIGS. 7A and 7B illustrates an example of a power quality premises list output by an end-user device.

FIGS. 8A and 8B illustrates another example of a power quality premises list output by an end-user device.

FIG. 9 illustrates an example of a customer premises view output by an end-user device.

FIG. 10 illustrates a flowchart of an example method for monitoring conditions of CTs.

### DETAILED DESCRIPTION

The present disclosure relates to a power monitoring system that monitors power data measured by current transformers (CTs) to passively determine an operational condition of the CTs. A CT monitors a power line provided to a customer premises (e.g., a commercial premises), such as an industrial manufacturer. Some conditions indicate that CTs are defective, improperly installed and/or underperforming, such that demand for a customer premises cannot be accurately calculated.

The power meters provide power data to the power monitoring system on a periodic or asynchronous basis. The power data is time stamped and includes a voltage magnitude, a voltage phase, a voltage angle, a current magnitude (e.g., in amperes), a current angle (e.g., in degrees) and a current phase (e.g., in degrees) that characterizes the power provided to a corresponding customer premises. Multiple instances of the power data are analyzed to determine if the CT is operating correctly. Stated differently, a CT monitoring system executing on a server, such as a utility server, employs the power data to determine an operational condition of a set of CTs of the metering device installed at the customer premises based on the power data. In particular, analysis of the power data reveals whether the CT is (i) connected backwards (e.g., reversed polarity), (ii) defective (e.g., has a short circuit/shunt) or (iii) oversized for the present load at the corresponding customer premises (iv) has a cross-phase or (v) operating properly. In a situation where a CT (or multiple CTs) are detected to be (i) connected backwards (e.g., reversed polarity), (ii) defective (e.g., has a short circuit/shunt) or (iii) oversized for the present load at the corresponding customer premises or (iv) has a cross-phase, a service crew can be deployed to a premise that can inspect and remedy the situation.

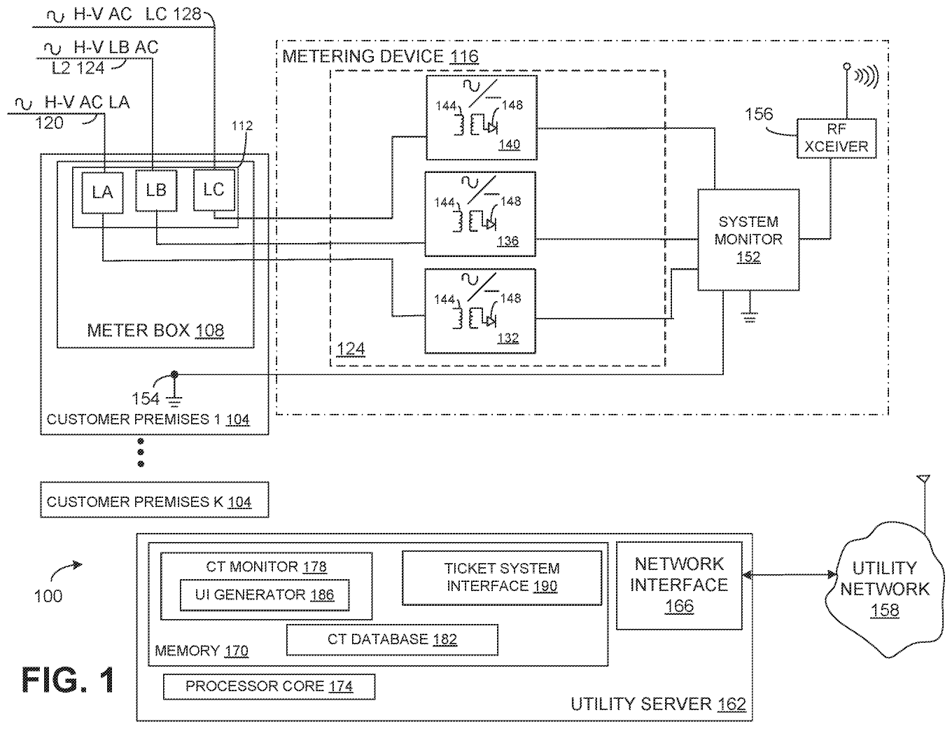

FIG. 1 illustrates an example of a system 100 for monitoring operational conditions (e.g., health) of CTs. CTs can be installed at K number of customer premises 104 that consume electricity, such as an industrial customer premises that receives polyphase power, such as three-phase power (abbreviated as 3ϕ), where K is an integer greater than or equal to one. In the example illustrated, the customer premises 104 receives three-phase power, but in other examples, the customer premises 104 can receive single phase power (abbreviated as 1ϕ). In some examples, three-phase power can be connected in a Wye (Y) configuration, a delta (Δ) configuration, a delta-Wye configuration or another configuration. Three-phase power refers to alternating current (AC) power provided on three lines that are each 120 degrees out of phase, or 180 degrees out of phase in examples where the three-phase power is in a delta (A) configuration. In some examples, certain operational conditions of CTs can impact an ability to accurately determine an instant demand of power consumed at customer premises.

The first customer premises 104 (customer premises 1-104) includes a meter box 108 with an inlet port 112 of a metering device 116. In the example illustrated, the inlet port 112 is coupled to three powerlines, namely the lines La 120, Lb 124 and Lc 128. Lines La 120, Lb 124 and Lc 128 are coupled to a transformer of a power grid. Lines La 120, Lb 124 and Lc 128 are configured to carry a high voltage (H-V) AC signal that are 120 degrees out of phase. In examples where one of the K number of customer premises 104 is configured with single phase power, the inlet port 112 is coupled to two AC signals that are 180 degrees out of phase.

Each line of the meter box 108 is coupled to a set of CTs. Specifically, in the example illustrated, line La 120 is coupled to a primary winding of CTa 132, line Lb 124 is coupled to a primary winding of CTb 136 and line Lc 128 is coupled to a primary winding CTc 140. CTa 132, CTb 136 and CTc 140 include a respective step-down transformer 144. In some examples, CTa 132, CTb 136 and CTc 140 can also include a diode 148 coupled to a corresponding secondary winding. In other examples, the diode 148 is omitted. The 2-Kth customer premises 104 can be configured in a similar manner.

The CTa 132, CTb 136 and CTc 140 provide an output signal to a system monitor 152 through the corresponding secondary winding. The output signal is a scaled down version of the power signal provided on the respective power line. More specifically, the output signal of CTa 132 represents a scaled down version of the power signal provided on line La 120. The output signal of CTb 136 represents a scaled down version of the power signal provided on line Lb 124 and the output signal of CTc 140 represents a scaled down version of the power signal provided on line Lc 128. The system monitor 152 can also be coupled to a ground node 154 of the customer premises 104. The system monitor 152 can be implemented with a controller or other device that can store and execute embedded machine-readable instructions. The system monitor 152 can communicate with a radio frequency (RF) transceiver 156 for communicating on a utility network 158, such as a private network (e.g., a mesh network) or a public network (e.g., the Internet) or some combination thereof. Nodes on the utility network 158 communicate through wireless communication channels, wired communication channels and/or optical communication channels (e.g., communication through fiber optic cables and/or free space optical communication channels). The 2-Kth customer premises 104 can be configured in a similar manner.

The system 100 includes a utility server 162, such as a computing platform. The utility server 162 can communicate with the utility network 158 through a network interface 166. The utility server 162 includes a (non-transitory) memory 170. The memory 170 is implemented as a non-transitory machine-readable medium, such as volatile and/or nonvolatile memory, including random access memory (RAM), a solid-state drive (SSD), a hard disk drive (HDD) or a combination thereof. The memory 170 stores data and machine-readable instructions. The utility server 162 also includes a processor core 174 (or multiple processor cores) configured to access the memory 170 and execute the machine-readable instructions.

The utility server 162 could be implemented in a computing cloud. In such a situation, features of the utility server 162, such as the processor core 174, the network interface 166 and the memory 170 could be representative of a single instance of hardware or multiple instances of hardware with applications executing across the multiple of instances (i.e., distributed) of hardware (e.g., computers, routers, memory, processors or a combination thereof). Alternatively, the utility server 162 could be implemented on a single dedicated server.

The memory 170 includes a CT monitor 178. The CT monitor 178 is configured to collect and analyze data from the metering devices 116 at the K number of customer premises 104 or some subset thereof. The CT monitor 178 can also store and retrieve historical data from a CT database 182. In the example illustrated, the CT database 182 is illustrated as being integrated with the utility server 162. In other examples, the CT monitor 178 is operating on an external system.

Periodically (e.g., once per day) and/or asynchronously, the CT monitor 178 can ping each system monitor 152 (or some subset thereof) of the K number of customer premises 104 for power data. Each instance of power data (or some subset thereof) can be stored in the CT database 182. The power data includes a voltage magnitude (e.g., in volts), a voltage angle (e.g., in degrees), a voltage phase (e.g., in degrees), a current magnitude (e.g., in amperes), a current angle (e.g., in degrees) and a current phase (e.g., in degrees) for each line (La, Lb and Lc for three-phase power) of power provided to the corresponding customer premises 104, as measured by the system monitor 152. The power data can be stored in the CT database 182. The CT monitor 178 can calculate a power factor, PF and an instant demand, ID for the K number of customer premises 104 using Equations 1-3.

$$PF = \frac{ID}{VA} \qquad Equation 1$$

$$ID = \sum ( Va * Ia * cos ( VaA - IaA ) * \frac{π}{180} ) + ( Vb * Ib cos ( VbA - IbA ) * \frac{π}{180} ) + ( Vc * Ic * cos ( VcA - IcA ) * \frac{π}{180} ) ) \qquad Equation 2$$

$$VA = \sum ( ( Va * Ia ) + ( Vb * Ib ) + ( Vc * Ic ) ) \qquad Equation 3$$

wherein:
Va is the magnitude of the voltage for phase a;
Ia is the magnitude of the current for phase a;
VaA is the voltage angle for phase a;
IaA is the current angle for phase a;
Vb is the magnitude of the voltage for phase b;
Ib is the magnitude of the current for phase b;
VbA is the voltage angle for phase b;
IbA is the current angle for phase b;
Vc is the magnitude of the voltage for phase c;
Ic is the magnitude of the current for phase c;
VcA is the voltage angle for phase c;
IcA is the current angle for phase c;
ID is the instant demand, in kilowatts (KW) for the corresponding customer premises; and
PF is the power factor for the power supplied to the corresponding customer premises.

The power data from each system monitor 152 can be monitored over a time frame (e.g., 7 days) and analyzed to determine an operational condition of the CTs associated with a customer premises 104. More specifically, the CT monitor 178 can determine if one or more associated CTs (e.g., the CTa 132, CTb 136 and/or CTc 140) is connected backwards, defective (or otherwise not properly functioning) or oversized. Thus, a numerical notation can be added to indicate an order of measurement. For example, IaA0 indicates a last measured current angle for phase a, IaA1 indicates a second to last measured current angle for phase a, IaA2 indicates a third to last measured current angle for phase a, etc.

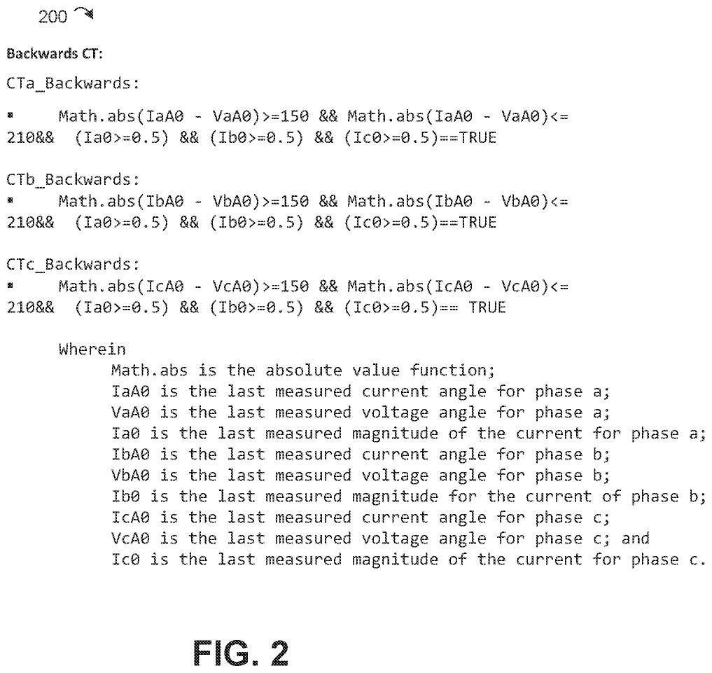

In a first example, (hereinafter, “the first example”), suppose that the CTa 132 of the first customer premises 104 is connected backwards (e.g., polarity reversed on a primary winding). As noted, the power data includes the voltage angle and the current angle for lines La 120, Lb 124 and Lc 128 of the customer premises 104. To determine if one of the CTa 132, CTb 136 and/or CTc 140 is connected backwards, the CT monitor 178 is configured to subtract the voltage angle from the current angle for each line (lines La, Lb and Lc). The CT monitor 178 is configured such that if the difference in voltage angle and current angle of a given phase (e.g., each phase can be tested) is between a range of 150 and 210 degrees and current (I) magnitude on the given phase is greater than or equal to 0.5 (or some other threshold value based on the environment in which the metering device 116 is implemented), the CT on the particular phase is backwards. The result is calculated as an absolute value. More generally, FIG. 2 illustrates pseudocode 200 employable by the CT monitor 178 to determine if the CTa 132, the CTb 136 and/or the CTc 140 is connected backwards. In the pseudocode 200, if the statements for CTa_Backwards, CTb_Backwards and/or CTc_Backwards is/are TRUE (Boolean value), it is presumed that the corresponding CT (CTa 132, CTb 136 and/or CTc 140) is connected backwards. It is understood that the values, such as the current magnitude provided in the pseudocode 200 are provided as examples that could vary based on the environment of application. Continuing with the first example, it is presumed that the CTa 132 for the first customer premises 104 is connected backwards, and the CTb 136 and the CTc 140 are connected properly (frontwards). Thus, in the pseudocode 200, it is presumed that in the first example, the value for CTa_Backwards would be TRUE and the value for CTb_Backwards and CTc_Backwards is FALSE. In a situation where the CT monitor 178 detects a CT connected backwards (e.g., reversed polarity) for one or more days (of a seven day period), the CT monitor 178 can set a backwards CT condition for the corresponding customer premises 104 indicating that the CT at the corresponding customer premises 104 should be inspected (e.g., the CTa 132 of the first customer premises 104 in the first example).

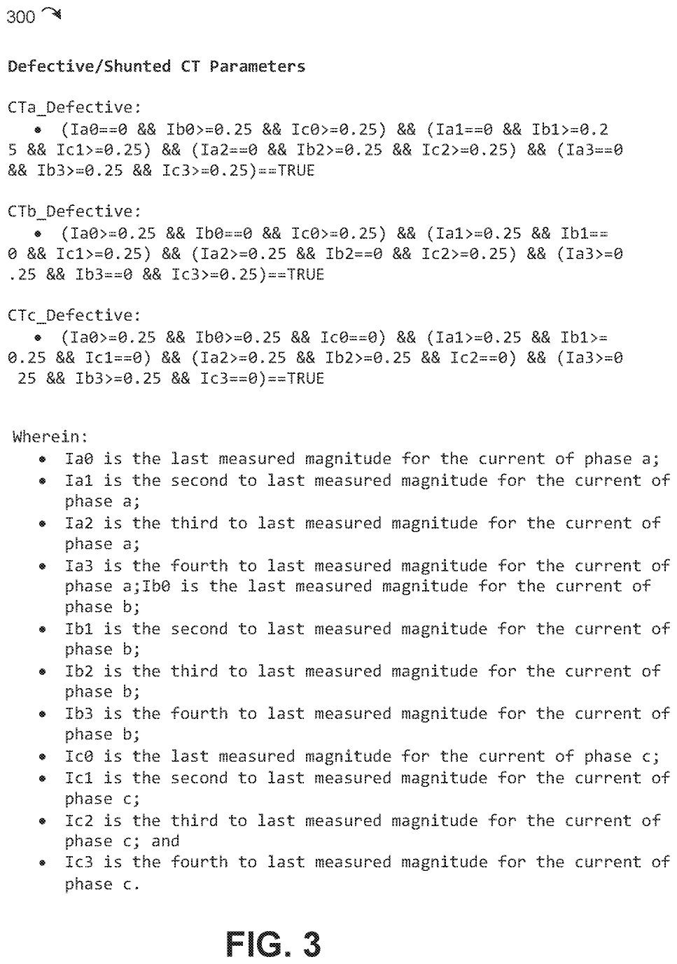

In a second example (hereinafter, “the second example”) suppose that the CTb 136 of the second customer premises 104 (e.g., customer premises 2-104) is defective, indicating that the CTb 136 either was installed improperly or has since failed. In the second example, it is also presumed that the CTa 132 and the CTc 140 of the second customer premises 104 are operating properly. To detect a defective CT for the K number of customer premises 104, the CT monitor 178 determines whether a phase of a particular CT (e.g., CTa 132, CTb 136 and/or CTc 140) has a current magnitude equal to zero (0) and where other current magnitudes are greater than or equal to a threshold (e.g., 0.25 or some other value), thus indicating that the particular CT is defective. To curtail false positives, the CT monitor 178 determines that the particular CT is defective if the defective condition is detected for a predetermined number of consecutive instances (e.g., four or more). More generally, FIG. 3 illustrates pseudocode 300 executable by the CT monitor 178 to detect a defective CT (alternatively referred to as a shunted CT). It is understood that the values, such as the current magnitude provided in the pseudocode 300 are provided as examples that could vary based on the environment of application. In the pseudocode 300, if the statements for CTa_Defective, CTb_Defective and/or CTc_Defective are TRUE (Boolean value), it is presumed that the corresponding CT (CTa 132, CTb 136 and/or CTc 140) is defective, such as due to a defective installation or an operational failure. Thus, in the pseudocode 300, it is presumed that in the second example, the value for CTb_Defective would be TRUE and the value for CTa_Defective and CTc_Defective is FALSE for the second customer premises 104. In a situation where the CT monitor 178 detects a defective CT, the CT monitor 178 can assert (e.g., set) a defective CT condition for the defective CT of the corresponding customer premises 104 indicating that the corresponding customer premises 104 should be inspected (e.g., the CTb 136 of the second customer premises 104 in the second example).

In a third example (hereinafter, “the third example”) suppose that the CTa 132, the CTb 136 and the CTc 140 of the third customer premises 104 (e.g., customer premises 3-104) are oversized. Secondary windings of oversized CTs are not energized by normal power consumption of a corresponding premises 104, such that actual instant demand, ID of the corresponding customer premises 104 cannot be accurately calculated. Stated differently, the output signal of a secondary winding of an oversized CT is not an accurate scaled down version of a power flowing through a corresponding power line. An oversized CT can occur in situations where operations of a particular customer premises 104 change. For instance, suppose that a particular set of CTs (CTa 132, CTb 136 and CTc 140) for a particular customer premises 104 are sized to accommodate an automotive manufacturer that consumes an instant demand of 100 KW on a peak basis. Now, suppose that the particular customer premises 104 is purchased and converted to a storage warehouse that consumes an instant demand of 5 KW. In this instance, the CTs installed at the particular customer premises 104 may not be energized, such that the instant demand for a particular customer premises 104 cannot be calculated accurately.

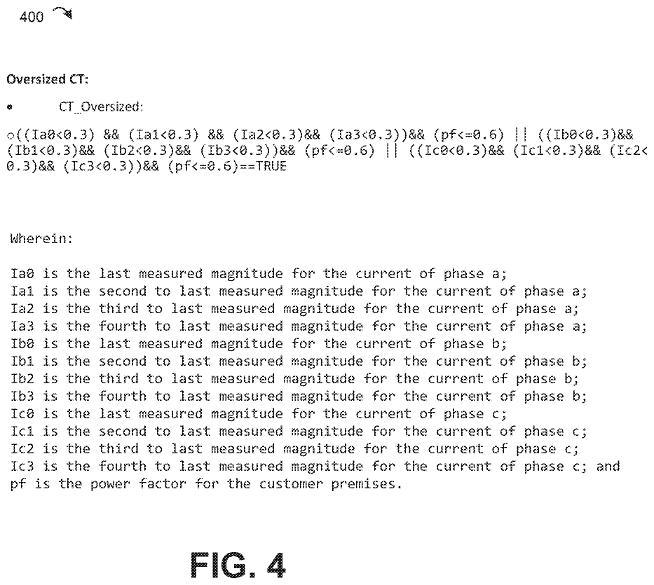

To detect oversized CTs (e.g., CTa 132, CTb 136 and CTc 140), the CT monitor 178 determines if the current magnitude across each phase is greater than zero and less than a given threshold (e.g., 0.3 or some other value) and the power factor, pf is less than or equal to another threshold (e.g., 0.6), indicating that the CTs may be oversized if this condition is present for four or more consecutive instances of measured power data, such that a confidence in the presence of a defect is increased. More generally, FIG. 4 illustrates pseudocode 400 executable by the CT monitor 178 to detect oversized CTs installed at a corresponding customer premises 104. It is understood that the values, such as the current magnitude and/or the power factor provided in the pseudocode 400 are provided as examples that could vary based on the environment of application. In the pseudocode 400, the test condition for the current magnitude being equal to zero (0) is excluded for purposes of simplicity of explanation. In the pseudocode 400, if the statement for CT_Oversized is TRUE (Boolean value), it is presumed that the corresponding CTs (CTa 132, CTb 136 and CTc 140) are oversized, such that instant demand, ID for the corresponding customer premises 104 is being accurately calculated. Thus, in the pseudocode 400, it is presumed that in the third example, the value for CT_Oversized would be TRUE. In response to detecting oversized CTs for a corresponding customer premises 104, the CT monitor 178 asserts an oversized CT condition indicating that the corresponding customer premises 104 should be inspected (e.g., the CTa 132, CTb 136 and CTc 140 of the first customer premises 104 in the third example). Accordingly, in the third example, the CT monitor 178 asserts an oversized CT condition for the third customer premises 104.

Further, the CT monitor 178 can detect whether two CTs of a particular customer premises 104 are cross-phased. Similar to oversized CTs, cross-phased CTs prevent accurate calculation of instant demand, ID of a corresponding customer premises 104. In a fourth example, (hereinafter, “the fourth example”) suppose the CTa 132 and the CTb 136 of the fourth customer premises 104 (e.g., customer premises 4-104) are cross-phased. For a particular customer premises 104, the CT monitor 178 determines that CTa 132 and CTb 136 of the particular customer premises 104 are cross-phased if a difference between the current angle and the voltage angle of phase a to phase b is less than or equal to 30 degrees. Additionally, the CT monitor 178 determines that the CTb 136 and the CTc 140 of a particular corresponding customer premises 104 are cross-phased if a difference between the current angle and the voltage angle of phase b to phase c is less than or equal to 30 degrees. Further, the CT monitor 178 determines that the CTa 132 and the CTc 140 of a corresponding customer premises 104 are cross-phased if a difference between the current angle and the voltage angle of phase a to phase c is less than or equal to 30 degrees.

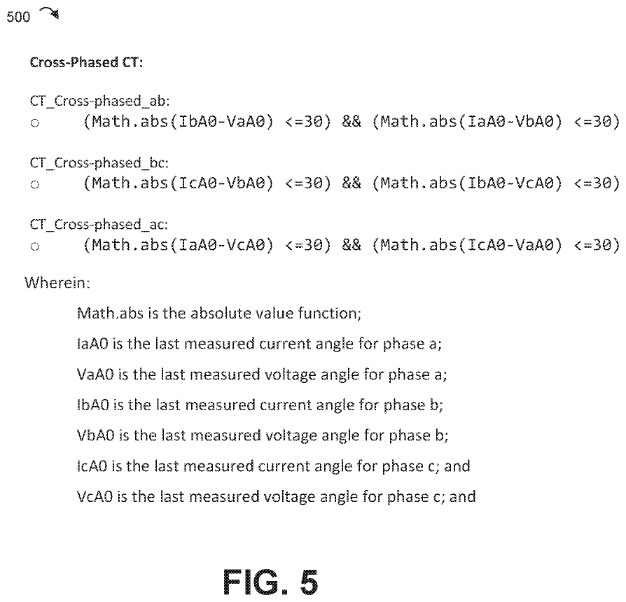

More generally, FIG. 5 illustrates pseudocode 500 executable by the CT monitor 178 to detect cross-phased CTs installed at a corresponding customer premises 104. It is understood that the values provided for the pseudocode 500 are provided as examples that could vary based on the environment of application. In the pseudocode 500, if the statement for CT_Cross-phase_ab is TRUE (Boolean value), it is presumed that the corresponding CTa 132 and CTb 136 are cross-phased. Additionally, if the statement for CT_Cross-phased_bc is TRUE, it is presumed that the corresponding CTb 136 and the CTc 140 of the corresponding customer premises 104 are cross-phased. Further, if the statement CT_Cross-phased_ac is TRUE, it is presumed that the CTa 132 and the CTc 140 of the corresponding customer premises 104 are cross-phased, such that instant demand, ID for the corresponding customer premises 104 is not being accurately calculated. Thus, in the pseudocode 500, it is presumed that in the fourth example, the value for CT_Cross-phased_ab would be TRUE, and CT_Cross-phased_bc and CT_Cross-phased_ac are both FALSE. The CT monitor 178 asserts a cross-phased CT flag in response to detecting a particular customer premises 104 that has a cross-phased CT. Accordingly, in the fourth example, the CT monitor 178 can assert the cross-phased CT condition for the CTa 132 and CTb 136 of the fourth customer premises 104.

The CT monitor 178 can employ power data received from the metering devices 116 of the K number of customer premises 104 to determine an operational condition of a set of CTs (e.g., CTa 132, CTb 136 and CTc 140) installed at the customer premises 104, such as a condition that prevents an accurate calculation of an instant demand, ID of power usage for the corresponding customer premises 104. More particularly, the CT monitor 178 can collect power data from the K number of customer premises 104 to detect customer premises 104 that includes a CT (or multiple CTs) that (i) is connected backwards, such that the backwards CT condition is asserted for a first subset of the K number of customer premises 104. Additionally, the CT monitor 178 can detect customer premises 104 with a (ii) defective CT or multiple defective CTs (e.g., due to improper installation or other reason), such that a defective CT condition is asserted for a second subset of the K number of customer premises 104. Also, the CT monitor 178 can detect customer premises 104 with (iii) oversized CTs, such that an oversized CT condition is asserted for a third subset of the K number of premises 104. Further, the CT monitor 178 can detect each customer premises 104 with (iv) a cross-phased CT, such that a cross-phased CT condition is asserted for a fourth subset of the K number of premises 104. Moreover, the conditions of the sets of CTs of the metering devices 116 of the K number of customer premises are not meant to be exhaustive. In other examples, the power data can be analyzed by the CT monitor 178 to determine other conditions of the sets of CTs as well.

The CT monitor 178 includes a user interface (UI) generator 186 that can output data characterizing a power status of each of the K number of customer premises 104 or some subset thereof. For example, the UI generator 186 can communicate with a web server and/or a dedicated client application operating on an end-user device (e.g., a desktop computer, a laptop computer or a mobile device) external to the system 100 to output the data characterizing the power status of the K number of customer premises 104, or some subset thereof. In some examples, the utility server 162 and the end-user device can communicate through the utility network 158 or another network (e.g., a public network, such as the Internet). The data can be organized by the UI generator 186 and output in a graphical user interface (GUI) operating on the end user device.

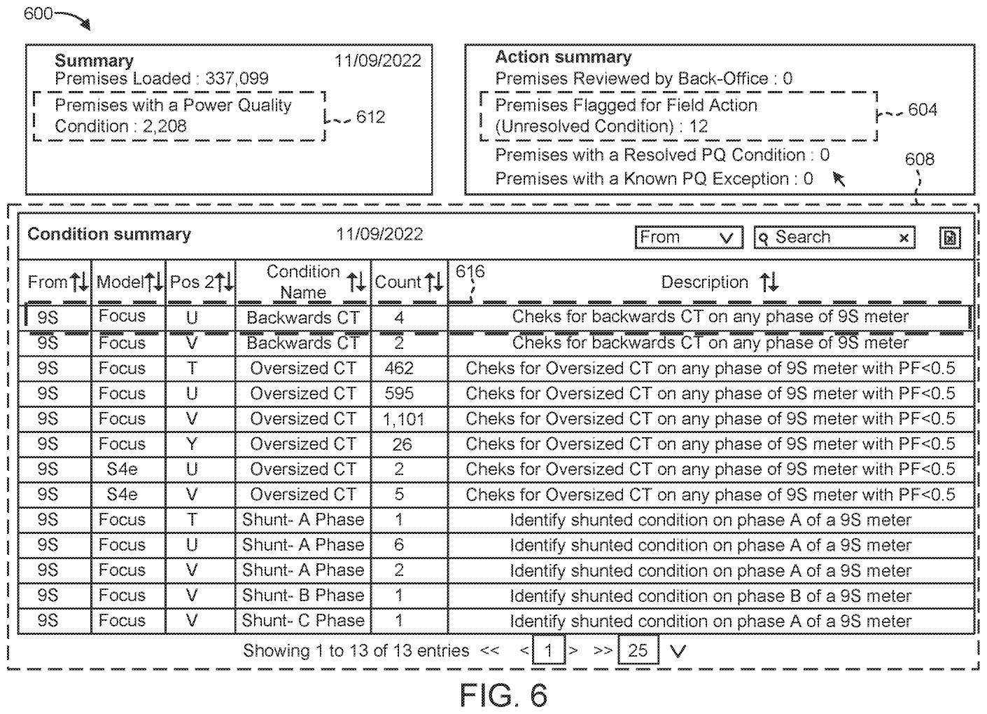

FIG. 6 illustrates an example of a dashboard 600 provided by the UI generator 186 that is output by an end-user device. The dashboard 600 includes a text box 604 that includes a number of premises flagged for field action (e.g., by a service crew). The text box 604 can include a hyperlink (e.g., a number) that can be actuated. Actuation of the hyperlink causes the UI generator 186 to provide a condition summary text box 608.

The condition summary text box 608 provides information identifying a model (e.g., manufacturer) of a meter, a type of power provided (e.g., three-phase Wye or Delta, single phase, etc.) and condition and a number of meters that are experiencing the condition. In one example, a condition description and a number of meters experiencing the condition that have a same power type is also included in the condition summary text box 608.

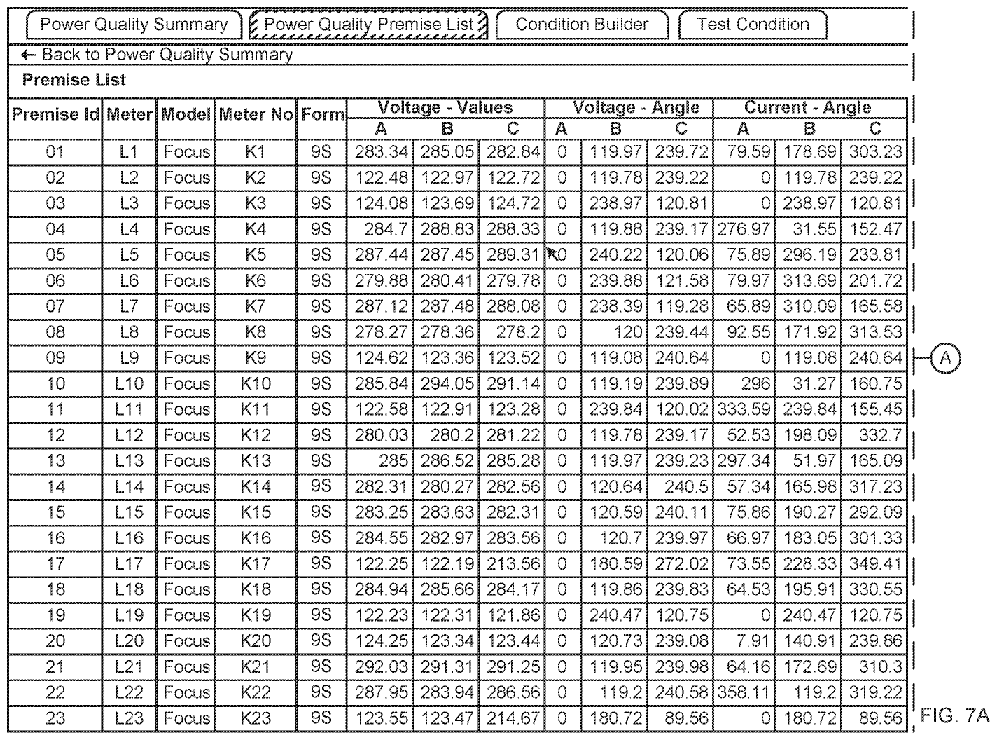

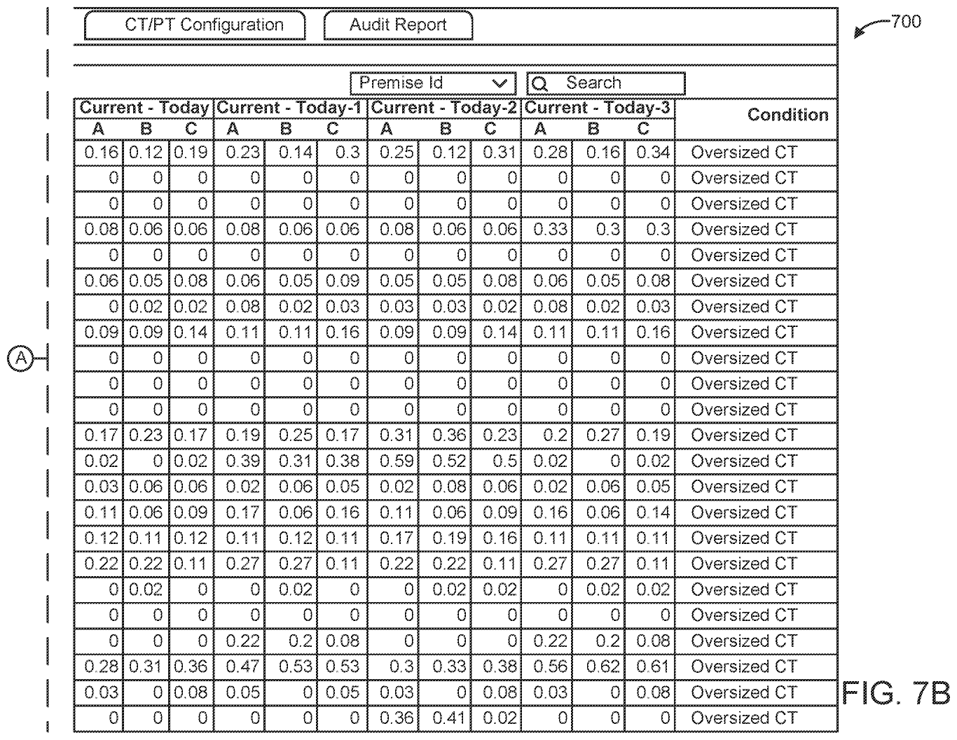

The dashboard 600 further includes a text box 612 that identifies an number of customer premises that have a power quality condition. Selection of a hyperlink in the text box 612 causes the UI generator 186 to output a power quality premises list. FIGS. 7A and 7B illustrate an example of a power quality premises list 700 output by an end-user device that includes a premises identifier (ID) to uniquely identify a particular customer premise, and a particular meter (e.g., a meter serial number). The power quality premises list 700 also provides data indicating a measured and/or calculated power data for a past four (4) days.

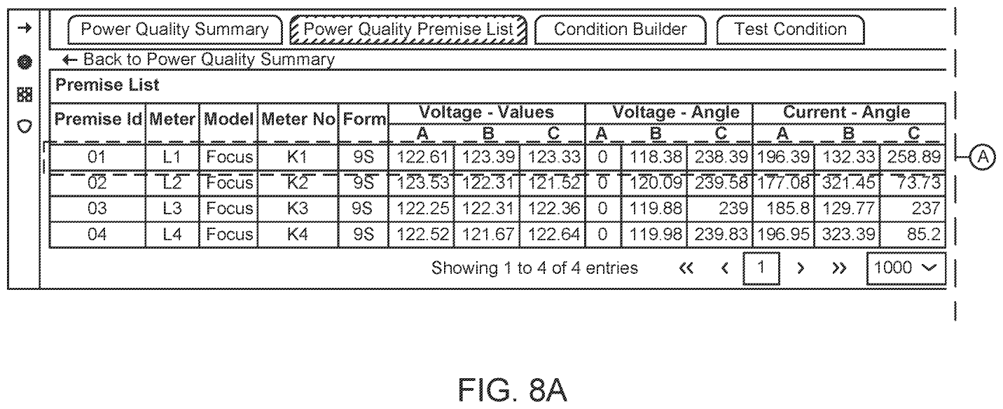

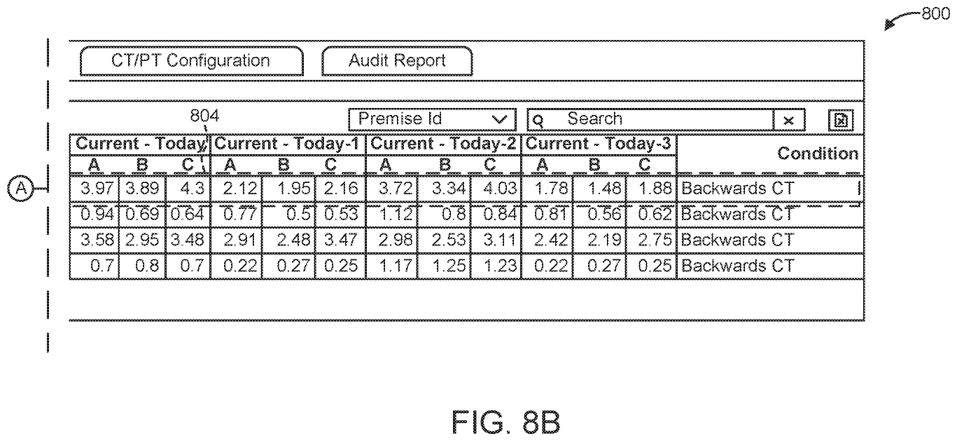

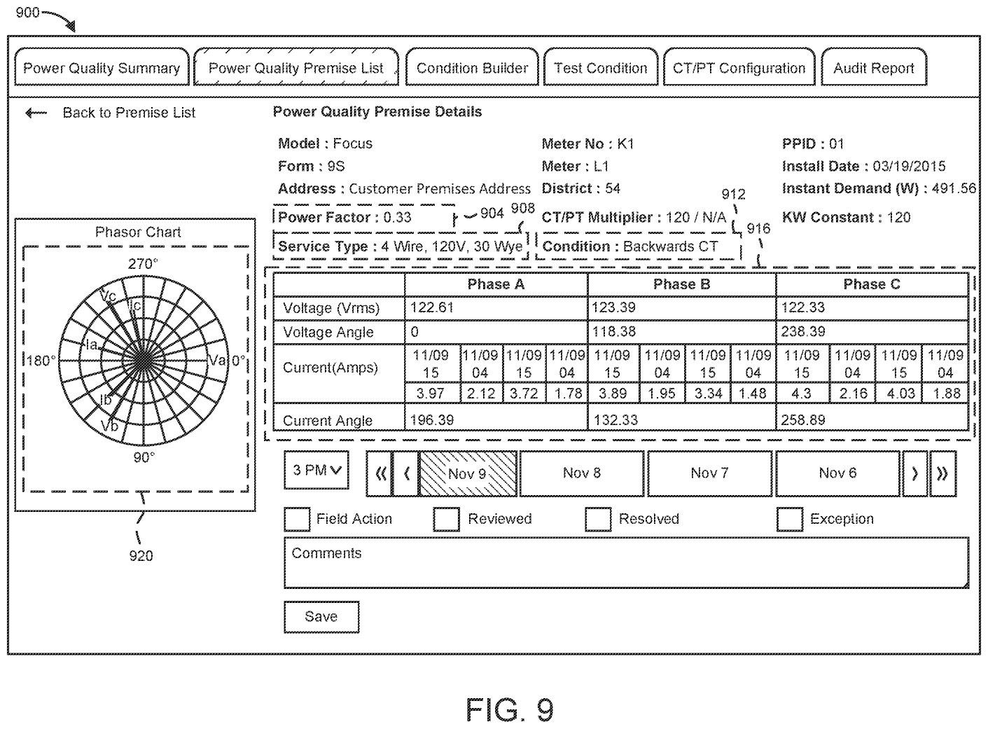

Referring back to FIG. 6, each row of the condition summary text box 608 includes a hyperlink that can be actuated to provide detailed information about each customer premises that is referenced in a corresponding row. In the example illustrated, a text box 616 represents a first row of the condition summary text box 608. In response to actuation of the hyperlink in the text box 616, the UI generator 186 can provide a list of premises that have a particular condition and associated details. FIGS. 8A and 8B illustrate an example of a power quality premises list 800 that includes a premises ID to uniquely identify a particular customer premise, and a particular meter (e.g., a meter serial number) output by an end-user device. The power quality premises list 800 also provides data indicating a measured and/or calculated power data for a past four (4) days. Each row on the power quality premises list 800 includes a hyperlink for viewing details of a particular customer premises 104. As an example, suppose that a hyperlink in a first row 804 is selected, and a premises view for the corresponding customer premises 104 is displayed. FIG. 9 illustrates an example of a customer premises view 900 output in response to section of the hyperlink on the first row 804 of FIGS. 8A and 8B that is output by an end-user device.

The customer premises view 900 includes detailed information for a single customer premises. This information includes a power factor 904, a service type 908 and a condition 912. The information also includes a voltage and current magnitude as well as voltage and current angles for each phase of the customer premises, as indicated in a text box 916.

The customer premises view 900 still further includes a phasor chart 920 that plots a last measured phase and magnitude (in visual form) for the corresponding premises. Because the condition 912 indicates a backwards CT, the voltage angle and the current angle are about 160 degrees out of phase for phase a in the illustrated example. Thus, the customer premises view 900 allows a user to quickly assess a situation and visually confirm findings of the CT monitor 178.

Referring back to FIG. 1, in some examples, the memory 170 can include a ticket system interface 190 that interfaces with the CT monitor 178. In such a situation, in response to assertion of a particular CT condition (e.g., a backwards CT condition, a defective CT condition, an oversized CT condition and/or a cross-phased CT condition), the CT monitor 178 can provide a ticket request characterizing the CT condition to the ticket system interface 190. More generally, the CT monitor 178 provides a ticket request characterizing a condition detected at a particular customer premises 104 responsive to determining that the set of CTs (e.g., CTa 132, CTb 136 and/or CTc 140) of the metering device 116 have a condition that prevents an accurate calculation of an instant demand of power usage for the particular customer premises 104. Responsive to this request, the ticket system interface 190 can communicate with a ticketing system (e.g., operating on an external system) to schedule deployment of a service crew to inspect and/or remedy an issue identified by the CT monitor 178.

By employment of the system 100, over time, a status of CTs and power quality of the K number of customer premises 104 can be evaluated. The system 100 obviates the need for periodic (e.g., yearly or even less frequent) visual inspections of CTs deployed at customer premises. Instead, as explained in the first-fourth examples, CTs (e.g., the CTa 132, CTb 136 and/or CTc 140) of a particular customer premises 104 may be malfunctioning (e.g., defective) or improperly installed (e.g., connected backwards, cross-phased or oversized), such that the instant demand, ID for the particular customer premises 104 is not accurately calculated. The system 100 enables automatic identification of such conditions, such that a service crew can be dispatched to address issues at particular CTs with a high degree of confidence that field service is needed.

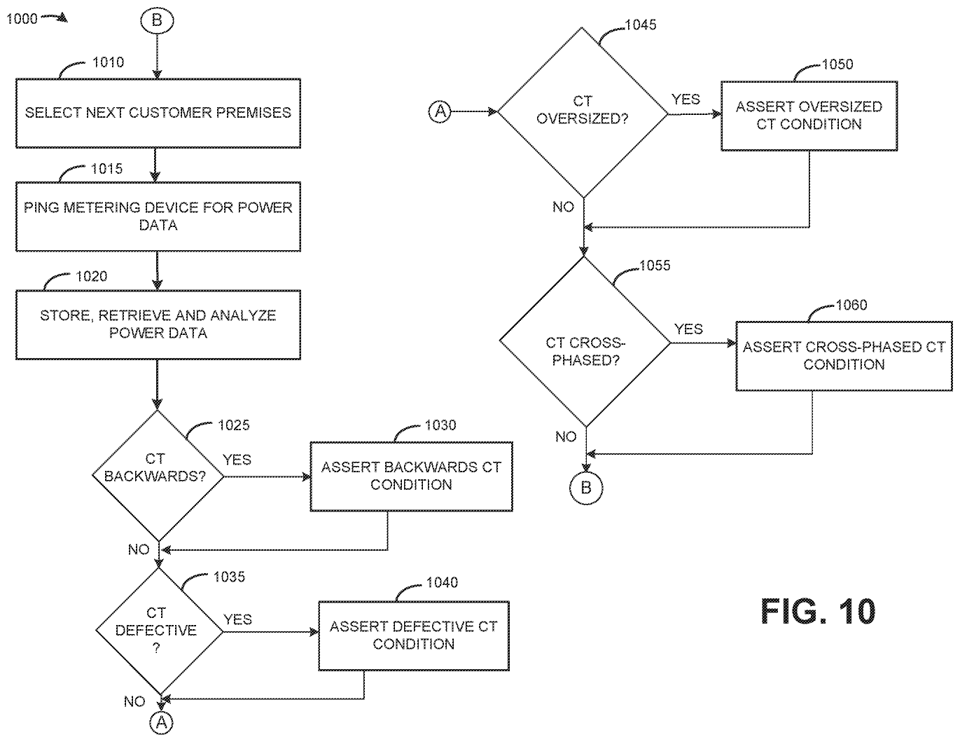

In view of the foregoing structural and functional features described above, an example method will be better appreciated with reference to FIG. 10. While, for purposes of simplicity of explanation, the example methods of FIG. 10 is shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement a method.

FIG. 10 illustrates a flowchart of an example method 1000 for determining the status of CTs at customer premises, such as the K number of customer premises 104 of FIG. 1. The method 1000 can be executed by a CT monitor (e.g., the CT monitor 178 of FIG. 1) operating on a computing platform, such as the utility server 162 of FIG. 1.

At 1010, the CT monitor selects a next customer premises for evaluation. At 1015, the CT monitor pings a metering device at the selected customer premises for power data. The power data can be provided through a utility network, such as the utility network 158 of FIG. 1. The power data includes a voltage magnitude, a voltage phase and a voltage angle for each phase of power lines provided to the selected customer premises. The power data also includes a current magnitude, a current phase and a current angle for each phase of power lines provided to the customer premises.

At 1020, the CT monitor stores (with a timestamp) the power data in a CT database, such as the CT database 182 of FIG. 1. At 1020, the CT monitor also retrieves prior instances of power data for the selected customer premises (e.g., a previous three instances) from the CT database, and analyzes the power data. The CT monitor can employ the power data to calculate a power factor and an instant demand for the selected customer premises using Equations 1-3.

At 1025, the CT monitor makes a determination as to whether a CT (or multiple CTs) at the selected customer premises is connected backwards (e.g., polarity reversed) based on the power data from the metering device at the selected customer premises, such that an accurate instant demand for the selected customer premises cannot be calculated. The determination at 1025 can be made, for example with the pseudocode 200 of FIG. 2. If the determination at 1025 is positive (e.g., YES), the method 1000 proceeds to 1030. If the determination at 1025 is negative (e.g., NO), the method 1000 proceeds to 1035. At 1030, the CT monitor asserts a backwards CT condition for the selected customer premises and the method 1000 proceeds to 1035.

At 1035, the CT monitor makes a determination as to whether a CT (or multiple CTs) at the selected customer premises is defective (e.g., improperly installed) such that the CT has a shunt (e.g., short circuit) based on the power data from the metering device at the selected customer premises, such that an accurate instant demand for the selected customer premises cannot be calculated. The determination at 1035 can be made, for example with the pseudocode 300 of FIG. 3, such that multiple instances (four) of power data are considered. If the determination at 1035 is positive (e.g., YES), the method 1000 proceeds to 1040. If the determination at 1035 is negative (e.g., NO), the method 1000 proceeds to 1045. At 1040, the CT monitor asserts a defective CT condition for the selected customer premises and the method 1000 proceeds to 1045.

At 1045, the CT monitor makes a determination as to whether the CTs at the selected customer premises are oversized, such that an accurate instant demand for the selected customer premises cannot be calculated. The determination at 1045 can be made, for example with the pseudocode 400 of FIG. 4, such that multiple instances (four) of power data are considered. If the determination at 1045 is positive (e.g., YES), the method 1000 proceeds to 1050. If the determination at 1045 is negative (e.g., NO), the method 1000 proceeds to 1055. At 1050, the CT monitor asserts an oversized CT condition for the selected customer premises and the method proceeds to 1045.

At 1055, the CT monitor makes a determination as to whether the CTs at the selected customer premises are cross-phased, such that an accurate instant demand for the selected customer premises cannot be calculated. The determination at 1055 can be made, for example with the pseudocode 500 of FIG. 5. If the determination at 1055 is positive (e.g., YES), the method 1000 proceeds to 1060. If the determination at 1045 is negative (e.g., NO), the method 1000 returns to 1010. At 1060, the CT monitor asserts a cross-phased CT condition for the selected customer premises and the method returns to 1010. Thus, over time, a status of the CTs for each of the customer premises can be ascertained such that a maintenance crew can be selectively deployed to inspect and remedy a condition.

In view of the foregoing structural and functional description, those skilled in the art will appreciate that portions of the systems and method disclosed herein may be embodied as a method, data processing system, or computer program product such as a non-transitory computer readable medium. Accordingly, these portions of the approach disclosed herein may take the form of an entirely hardware embodiment, an entirely software embodiment (e.g., in a non-transitory machine-readable medium), or an embodiment combining software and hardware. Furthermore, portions of the systems and method disclosed herein may be a computer program product on a computer-usable storage medium having computer readable program code on the medium. Any suitable computer-readable medium may be utilized including, but not limited to, static and dynamic storage devices, hard disks, optical storage devices and magnetic storage devices.

Certain examples have also been described herein with reference to block illustrations of methods, systems and computer program products. It will be understood that blocks of the illustrations, and combinations of blocks in the illustrations, can be implemented by computer-executable instructions. These computer-executable instructions may be provided to one or more processors of a general-purpose computer, special purpose computer, or other programmable data processing apparatus (or a combination of devices and circuits) to produce a machine, such that the instructions, which execute via the one or more processors, implement the functions specified in the block or blocks.

These computer-executable instructions may also be stored in computer-readable memory that can direct a computer or other programmable data processing apparatus to function in a particular manner, such that the instructions stored in the computer-readable memory result in an article of manufacture including instructions which implement the function specified in the flowchart block or blocks. The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions specified in the flowchart block or blocks.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described is this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

What have been described above are examples. It is, of course, not possible to describe every conceivable combination of components or methodologies, but one of ordinary skill in the art will recognize that many further combinations and permutations are possible. Accordingly, the disclosure is intended to embrace all such alterations, modifications and variations that fall within the scope of this application, including the appended claims. As used herein, the term “includes” means includes but not limited to, the term “including” means including but not limited to. The term “based on” means based at least in part on. Additionally, where the disclosure or claims recite “a,” “an,” “a first,” or “another” element, or the equivalent thereof, it should be interpreted to include one or more than one such element, neither requiring nor excluding two or more such elements.

What is claimed is:

1. A non-transitory machine-readable medium having machine-readable instructions for a current transformer (CT) monitor, the machine-readable instructions for the CT monitor being executable by a processor core to perform operations comprising:
receiving power data from a metering device operating on a customer premises, the power data characterizing features of electrical power provided to the customer premises; and
determining, from the power data, an operational condition of a set of CTs of the metering device installed at the customer premises based on the power data, wherein the operational condition of the set of CTs impacts an ability to accurately calculate a demand of power consumed by the customer premises.

2. The non-transitory medium of claim 1, wherein the power data characterizes a voltage magnitude, a voltage angle, a voltage phase, a current magnitude, a current angle and a current phase for the electrical power provided to the customer premises, wherein the operations of the CT monitor further comprise calculating a power factor for power provided to the customer premises based on the power data.

3. The non-transitory medium of claim 2, wherein the customer premises receives single or polyphase power through power lines, and each CT in the set of CTs is coupled to a corresponding power line of the single or polyphase power.

4. The non-transitory medium of claim 3, wherein the operations of the CT monitor further comprise calculating a demand for the single or polyphase power provided to the customer premises based on the power data.

5. The non-transitory medium of claim 3, wherein the operations of the CT monitor further comprise determining whether a given CT in the set of CTs is connected backwards based on the current angle, the voltage angle and the current magnitude for phases of the single or polyphase power provided to the customer premises.

6. The non-transitory medium of claim 5, wherein the determination of whether the given CT in the set of CTs is connected backwards is based on a determination that a current at each CT in the set of CTs has a current is greater than 0.5 amperes, and a difference in a current angle a voltage angle of the given CT is greater than or equal to 150 degrees and less than or equal to 210 degrees.

7. The non-transitory medium of claim 3, wherein the operations of the CT monitor further comprise determining whether a first CT and a second CT in the set of CTs are cross-phased based on the current angle and the voltage angle and the current magnitude for phases of the single or polyphase power provided to the customer premises.

8. The non-transitory medium of claim 7, wherein the determination of whether the first CT and the second CTs are cross-phased is based on a determination that a difference in a current angle and a voltage angle of the first CT and the second CT is less than or equal to 30 degrees.

9. The non-transitory medium of claim 8, wherein the power data is a last measured instance of power data for the customer premises, and the operations of the CT monitor further comprise retrieving, from a CT database, previous measured instances of power data for the customer premises, and each measured instance of power data for the customer premises, and each measured instance of power data includes a voltage magnitude, a voltage angle, a voltage phase, a current magnitude, a current angle and a current phase for phases of the single or polyphase power provided to the customer premises.

10. The non-transitory medium of claim 9, wherein the operations of the CT monitor further comprise determining whether a given CT in the set of CTs is defective based on the current magnitude of the last measured instance of power data and the current magnitude of previous measured instances of power data for single or polyphase power provided to the customer premises.

11. The non-transitory medium of claim 10, wherein the operations for determining whether the given CT of the set of CTs is defective further comprise determining that the current magnitude of the given CT is zero for at least three measured instances of the power data, and that the current magnitude for other CTs in the set of CTs is greater than 0.25 amperes for the at least three measured instances of power data.

12. The non-transitory medium of claim 2, wherein the operations of the CT monitor further comprise determining the set of CTs are oversized based on the current magnitude of a last measured instance of power data being less than a threshold and the current magnitude of previous measured instances of power data for power provided to the customer premises being less than the threshold.

13. The non-transitory medium of claim 12, wherein the threshold is 0.3 amperes, and operations for determining the set of CTs is oversized further comprising determining that the last measured instance and the previous measured instances of power data has a current magnitude that is greater than zero and a power factor that is less than or equal to 0.6.

14. The non-transitory medium of claim 1, wherein the CT monitor comprises a user interface (UI) generator that outputs data for a graphical user interface (GUI) characterizing the power data at the customer premises, the GUI including a phasor chart for single or polyphase power provided to the customer premises, and the GUI includes a unique identifier for the customer premises.

15. The non-transitory medium of claim 1, wherein the operations for the CT monitor further comprise generating a ticket request characterizing a condition detected at the customer premises responsive to determining that the set of CTs of the metering device have a condition that prevents an accurate calculation of an instant demand of power usage for the customer premises.

16. A system for monitoring current transformers (CTs), the system comprising:
a non-transitory memory having machine-readable instructions; and
a processor core that accesses the memory and executes the machine-readable instructions, the machine-readable instructions comprising a CT monitor that:
receives power data from a metering device operating on a customer premises for power data for single or polyphase power provided to the customer premises, the power data characterizing a voltage magnitude, a voltage angle, a voltage phase, a current magnitude, a current angle and a current phase for phases of the single or polyphase power provided to the customer premises; and
determines, based on the power data, an operational condition of a set of CTs of the metering device installed at the customer premises based on the power data, and each CT in the set of CTs is coupled to a corresponding power line of the single or polyphase power.

17. The system of claim 16, wherein the CT monitor calculates a power factor for the single or polyphase power provided to the customer premises based on the power data and a demand for the single or polyphase power provided to the customer premises based on the power data.

18. The system of claim 16, wherein the CT monitor determines if the set of CTs includes a (i) CT connected backwards, (ii) a defective CT, (iii) oversized CTs and/or (iv) cross-phased CTs based at least in-part on the power data.

19. A method for monitoring current transformers (CTs), the method comprising:
receiving power data at a CT monitor executing on a server from a metering device operating on a customer premises, the power data for single or polyphase power provided to the customer premises, the power data characterizing a voltage magnitude, a voltage angle, a voltage phase, a current magnitude, a current angle and a current phase for phases of the single or polyphase power provided to the customer premises; and
determining, based on the power data, an operational condition of a set of CTs of the metering device installed at the customer premises based on the power data, and each CT in the set of CTs is coupled to a corresponding power line of the single or polyphase power.

20. The method of claim 19, wherein the determining includes the CT monitor determining if the set of CTs includes a (i) CT connected backwards, (ii) a defective CT, (iii) oversized CTs and/or (iv) cross-phased CTs based at least in-part on the power data.
